(19) United States
(12) Patent Application Publication
(10) Pub. No.: US 2025/0204001 A1
(43) Pub. Date: Jun. 19, 2025

(54) SELF-ALIGNED BACKSIDE DIFFUSION BREAK AND S/D CONTACT

(71) Applicant: INTERNATIONAL BUSINESS MACHINES CORPORATION, Armonk, NY (US)

(72) Inventors: Tsung-Sheng Kang, Ballston Lake, NY (US); Tao Li, Slingerlands, NY (US); Ruilong Xie, Niskayuna, NY (US); Chih-Chao Yang, Glenmont, NY (US)

(21) Appl. No.: 18/542,034

(22) Filed: Dec. 15, 2023

(51) Int. Cl. H01L 29/417; H01L 23/528; H01L 29/06

(52) U.S. Cl. CPC H10D 64/254; H01L 23/5286; H10D 62/102

(57) ABSTRACT

A semiconductor device includes source/drain regions laterally disposed relative to one another in a row on a backside of the semiconductor device. A diffusion break is disposed between two adjacent source/drain regions and extends toward the backside between two source/drain region contacts. The diffusion break includes a different lateral dimension between the two adjacent source/drain regions than between the two source/drain region contacts.

### BACKGROUND

The present invention generally relates to semiconductor devices and processing methods, and more particularly to diffusion breaks applied from a backside of a device to isolate adjacent devices.

To isolate nearby devices from each other, diffusion breaks have been employed by removing components from a top side and depositing dielectric material in a space vacated by the removed component. As device nodes have decreased, the removal of the component, which tends to be smaller, is more difficult and any fill with dielectric material is even more complex. Deep reactive ion etching (RIE) can generate deep and narrow openings, but a small opening window makes it exceedingly difficult to remove the component and then provide a complete fill of the vacant space. If the vacant space is not properly filled, the diffusion break cannot properly function to electrically isolate nearby devices. This gets more pronounced as the aspect ratio of the opening created increases. Even if it is possible to remove and fill in a region with a diffusion break, extra lithographic steps are needed using other extreme ultraviolet (EUV) to accommodate the small feature size.

Therefore, a need exists for a diffusion break that can be reliably formed deep into a device without risking inadequate fill within a vacated region. A further need exists for a more reliable diffusion break in an environment of ever-decreasing node sizes.

### SUMMARY

In accordance with an embodiment of the present invention, a semiconductor device includes source/drain regions laterally disposed relative to one another in a row. A diffusion break is disposed between two adjacent source/drain regions and extends toward the backside between two source/drain region contacts. The diffusion break includes a different lateral dimension between the two adjacent source/drain regions than between the two source/drain region contacts.

In other embodiments, the diffusion break can include a portion that extends beyond the source/drain regions opposite the backside of the device. This portion of the diffusion break can include sidewall spacers. The diffusion break can include a wider portion between the two source/drain region contacts than between the two adjacent source/drain regions. The wider portion of the diffusion break can narrow toward the two adjacent source/drain regions such that a contact area between respective source/drain region contacts and corresponding source/drain regions is increased. The diffusion break can extend from a replacement metal gate layer to a backside power distribution network toward the backside of the device. A backside interlevel dielectric layer can be disposed between the backside power distribution network and the diffusion break. The diffusion break can include a narrower portion between the two source/drain region contacts than between the two adjacent source/drain regions to permit the two source/drain region contacts to be larger. The diffusion break can be disposed in a gate region, and the diffusion break can replace a gate. The diffusion break can be disposed in a device channel region, and the diffusion break can replace a device channel.

In accordance with another embodiment of the present invention, a semiconductor device includes a frontside and a backside, opposite the front side, and source/drain regions laterally disposed relative to one another. A diffusion break is disposed between two adjacent source/drain regions and has an upper portion and a lower portion. The upper portion is disposed in a gate region, and the lower portion separates backside source/drain region contacts.

In other embodiments, the upper portion of the diffusion break can include sidewall spacers. The diffusion break can include a wider portion between the backside source/drain region contacts than between the source/drain regions. The wider portion of the diffusion break can narrow toward the source/drain regions such that a contact area between respective backside source/drain region contacts and corresponding source/drain regions is increased. The diffusion break can extend from a replacement metal gate layer to a backside power distribution network. A backside interlevel dielectric layer is disposed between the backside power distribution network and the lower portion of the diffusion break. The diffusion break can include a narrower portion between the backside source/drain region contacts than between the source/drain regions to permit the source/drain region contacts to be larger. The diffusion break can be disposed in a gate region, and the diffusion break can replace a gate. The diffusion break can be disposed in a device channel region, and the diffusion break can replace a device channel.

In accordance with another embodiment of the present invention, a semiconductor device, includes a frontside and a backside opposite the front side, source/drain regions laterally disposed relative to one another; and a diffusion break disposed between two adjacent source/drain regions and having an upper portion and a lower portion. The upper portion is disposed in a gate region, and the lower portion separates backside source/drain region contacts. The lower portion includes a wider portion between the backside source/drain region contacts than between the source/drain regions such that a contact area between respective backside source/drain region contacts and corresponding source/drain regions is increased. The e upper portion of the diffusion break can include sidewall spacers.

In accordance with another embodiment of the present invention, a semiconductor device, includes a frontside and a backside opposite the frontside, source/drain regions laterally disposed relative to one another and backside source/drain region contacts connected to two adjacent source/drain regions from the backside. A diffusion break is disposed between the two adjacent source/drain regions and has an upper portion and a lower portion. The upper portion is disposed in a gate region, and the lower portion separates the backside source/drain region contacts. The diffusion break includes a wider portion between the backside source/drain region contacts than between the source/drain regions, and the wider portion narrows toward the source/drain regions. A backside interlevel dielectric layer is disposed between a backside power distribution network and the lower portion of the diffusion break. The upper portion of the diffusion break can include sidewall spacers. The diffusion break can extend between a replacement metal gate layer to the backside power distribution network.

In accordance with another embodiment of the present invention, a semiconductor device, includes a frontside and a backside opposite the frontside, source/drain regions laterally disposed relative to one another and backside source/drain region contacts connected to two adjacent source/drain regions from the backside. A diffusion break is disposed between the two adjacent source/drain regions and has an upper portion and a lower portion. The upper portion is disposed in a gate region, and the lower portion separates the backside source/drain region contacts. The lower portion of the diffusion break includes a tapered shape between the backside source/drain region contacts to permit the backside source/drain region contacts to be larger. A backside interlevel dielectric layer is disposed between a backside power distribution network and the lower portion of the diffusion break.

In accordance with another embodiment of the present invention, a semiconductor device includes a frontside and a backside opposite the frontside, source/drain regions laterally disposed relative to one another, backside source/drain region contacts connected to two adjacent source/drain regions from the backside and a diffusion break disposed between the two adjacent source/drain regions and having an upper portion and a lower portion. The upper portion is disposed in a gate region and the lower portion separates the backside source/drain region contacts.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a semiconductor device taken at section line X1 having a row of source/drain regions, with associated placeholders and gate structures and a layout view showing where section X1 is taken, in accordance with an embodiment of the present invention;

FIG. 2 shows a cross-sectional view taken at section line X1 after a portion of a substrate has been removed from a backside of the device, in accordance with an embodiment of the present invention;

FIG. 3 shows a cross-sectional view taken at section line X1 after patterning and etching an opening and cavity for placement of a diffusion break, the opening including a wider funnel shape to improve dielectric fill, in accordance with an embodiment of the present invention;

FIG. 4 shows a cross-sectional view taken at section line X1 after formation of the diffusion break, which extends toward the backside through a gate region and S/D regions, in accordance with an embodiment of the present invention;

FIG. 5 shows a cross-sectional view taken at section line X1 after additional backside interlevel dielectric is optionally deposited, in accordance with an embodiment of the present invention;

FIG. 6 shows a cross-sectional view taken at section line X1 after forming backside contact holes, in accordance with an embodiment of the present invention;

FIG. 7 shows a cross-sectional view taken at section line X1 after etching away remaining regions or portions of the placeholders, in accordance with an embodiment of the present invention;

FIG. 8 shows a cross-sectional view taken at section line X1 after depositing and recessing conductive material to form backside source/drain region contacts, in accordance with an embodiment of the present invention;

FIG. 9 shows a cross-sectional view taken at section line X1 after forming backside contact holes which are larger due to a reduction or narrowing of a profile of the diffusion break, in accordance with an embodiment of the present invention; and

FIG. 10 shows a cross-sectional view taken at section line X1 after depositing and recessing conductive material to form enlarged backside source/drain region contacts, in accordance with an embodiment of the present invention.

### DETAILED DESCRIPTION

In accordance with embodiments of the present invention, devices and methods are described which include forming diffusion breaks deep within a semiconductor device. The diffusion breaks can be formed more reliably using a fill process that does not require a high aspect ratio opening. High aspect ratio openings can experience pinch off or incomplete filling. Instead, filling the diffusion breaks more locally from a backside of the semiconductor device can reduce the aspect ratio of a cavity to be filled. Further, openings for a fill process to fill the cavity can be made larger. By improving the fill process, the quality of diffusion break is also improved and the diffusion break becomes more reliable.

In useful embodiments, a field effect transistor (FET) device includes a single diffusion break that extends from a gate, e.g., a replacement metal gate (RMG) level, to a backside source/drain (S/D) contact (BSCA) level. A profile of the S/D contact is wider as the profile progresses closer to S/D regions from a backside power distribution network (BSPDN). A backside single diffusion break in accordance with the embodiments of the present invention permits an easier dielectric fill and etch due to a lower aspect ratio provided by a larger opening. Further, using a backside to access the diffusion break shortens a depth needed to deposit the diffusion break reliably is greater reduced (shortened). In addition, in many designs, a backside of the device is less populated (e.g., more space is available on the backside of wafer), it is easier to process the diffusion break in accordance with embodiments of the present invention.

In an embodiment, a method for forming a semiconductor device includes forming a diffusion break from a backside of the device. After front end of the line (FEOL), middle end of the line (MOL) and back end of the line (BEOL) processes are completed on a frontside of the device, a carrier wafer is bonded to enable a wafer flip so that processing can continue on a backside of the device. A substrate is removed from the backside of the device. This can include removing a first portion of the substrate by an etch that stops on an etch stop layer. The etch stop layer and a remainder of the substrate can be removed.

Placeholders that are formed within trenches in the substrate are employed as a hard mask to perform a self-aligned single diffusion break reactive ion etch (RIE). Then, the single diffusion break region is filled with a dielectric material. Next, backside contacts are formed by etching openings and filling the openings with conductive material. The placeholder and placeholders that area shadowed by a profile of single diffusion break are removed. Processing can continue with the formation of the BSPDN and other structures on the backside of the device. Other embodiments include forming enlarged backside contacts by removing a portion of the diffusion break to enable extra space for the backside contacts.

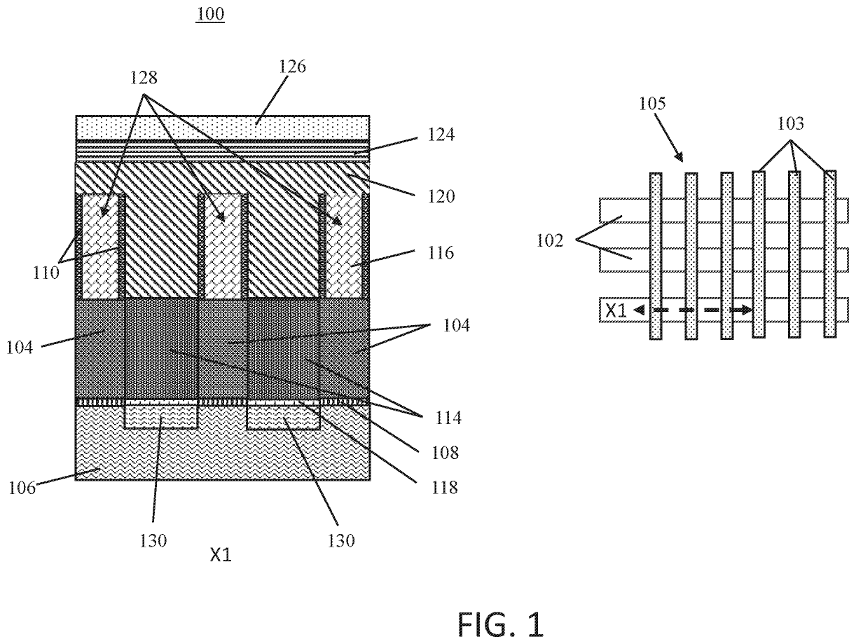

Referring now to the drawings in which like numerals represent the same or similar elements and initially to FIG. 1, devices and methods for manufacturing a semiconductor device are shown in accordance with embodiments of the present invention. The semiconductor device can include a nanosheet channel field effect transistor (FET) device, where a frontside (e.g., top) and a backside (bottom) of the device are processed.

An inset 105 shows a layout view where a section line X1 indicates a position in the layout view where cross-section X1 is taken. Inset 105 include gate lines 103 and active regions 102 orthogonally disposed relative to one another.

A semiconductor device or wafer 100 includes a substrate 106 that can have multiple layers on which the semiconductor device will be fabricated. The substrate 106 can include any suitable substrate structure or material, e.g., a bulk semiconductor, a semiconductor-on-insulator (SOI) substrate, etc., and preferably includes a monocrystalline semiconductor. In one example, the substrate 106 can include substrate portions separated by an etch stop layer (not shown).

Substrate 106 preferably includes silicon-containing material. Illustrative examples of Si-containing materials suitable for the substrate 106 can include, but are not limited to Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A layer stack or stacks are applied to or formed on the substrate 106. In one embodiment, one or more nanosheets (NS) 104 are applied to the substrate 106. The nanosheets 104 include semiconductor layers, which function as channels between source/drain regions 114. The S/D regions 114 have associated placeholders 130 formed in trenches within the substrate 106. A buffer 118 can be provided between the S/D region 114 and the placeholder 130. The buffer 118 can include Si. In one embodiment, the substrate 106 also includes Si, and the placeholders 130 include SiGe, to provide selectable etching between the substrate 106 and the placeholders 130.

In useful embodiments, active regions 102 include S/D regions 114 laterally disposed relative to one another in a row. Regions between adjacent source/drain regions 114 include gate structures 128 (gate lines 103). The gate structures 128 can have device channels (nanosheets 104) passing therethrough. Other device architectures are also contemplated and the gate structures and the device channels can take other forms.

The gate structures 128 are formed between S/D regions 114. The gate structures 128 can include gate dielectric (not shown) in contact with semiconductor materials of the nanosheets 104 which form the device channels, in this illustrative example. A gate metal or gate electrode 116 is provided. The gate structures 128 can include Replacement Metal Gate (RMG) structures. The gate metal or gate electrode 116 is electrically isolated from the substrate 106 by a bottom dielectric interface (BDI) 108. The gate metal or gate electrode 116 is also electrically isolated by dielectric sidewall spacers 110.

A dielectric layer 120, such as, e.g., an interlevel dielectric layer (ILD) can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 120 can be deposited using chemical vapor deposition (CVD), although other deposition methods can be employed.

Middle of the line (MOL) contacts (not shown) can be formed to make connections with the S/D regions 114 from a top side of the device or wafer 100. In useful embodiments, a silicide liner (not shown), such as Ti, Ni, NiPt is deposited first, then a diffusion barrier (not shown) can be formed in the trenches prior to a conductive fill. The diffusion barrier can include, e.g., TiN, TaN, or similar materials. The contacts can include materials, such as, e.g., Cu, Ru, Mo, Rh, W, Ir, and alloys or combinations of these and other conductive materials.

A back end of the line (BEOL) layer 124, which can include metal structures and dielectric layers, completes a top region and provides electrical access to earlier formed conductive structures. A carrier wafer 126 can be bonded to the BEOL layer 124. The carrier wafer 126 provides support and transportability to the wafer 100 for further processing which can include flipping the wafer 100 and removing portions of a bottom or backside of the device.

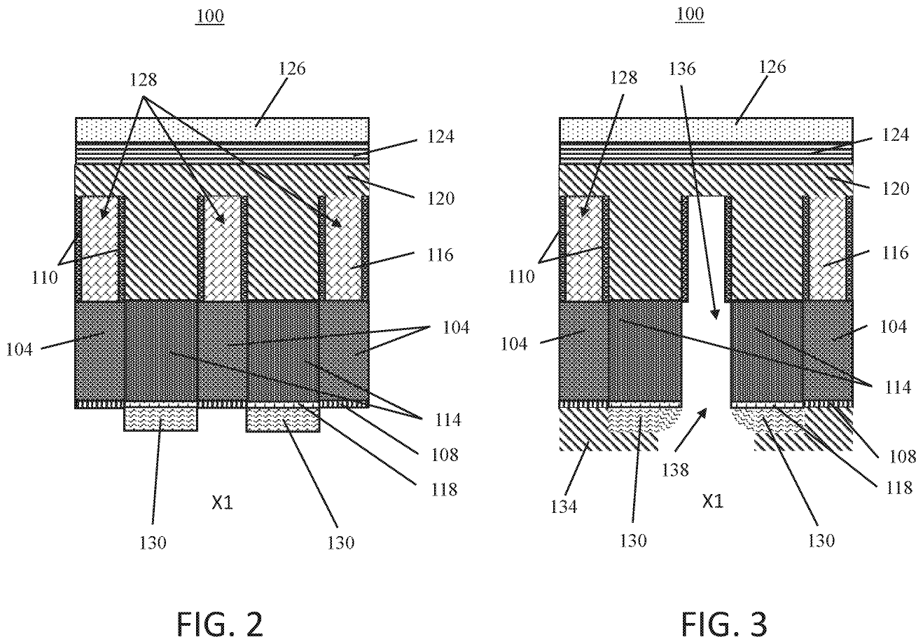

Referring to FIG. 2, to continue processing, the wafer 100 can be flipped to process features on the bottom side of the device. However, for clarity and consistency, the device will be shown in the FIGS. in a same orientation as previously described with continued and consistent reference to bottom/top. The substrate 106 is removed from the backside of the device. In one embodiment, the substrate 106 can be removed in portions by an etch process that stops on the etch stop layer. The etch stop layer is then removed by an etch process. Then, the etch can continue to remove the remaining portions of the substrate 106.

The substrate 106 is etched back by, e.g., a wet etch process that selectively removes the material relative to the placeholders 130. The placeholders 130 and BDI 108 function as an etch stop and remain for further processing.

Referring to FIG. 3, a dielectric layer 134 (e.g., a backside interlevel dielectric layer (BILD)) is formed over the placeholders 130 and BDI 108. The dielectric layer 134 can include similar materials and formation processes as dielectric layer 120. The dielectric layer 134 may be planarized, e.g., by CMP.

A mask material (not shown) is deposited or spun onto a surface of the wafer 100. In one embodiment, the mask material includes a hard mask material that can be patterned using photolithography, e.g., using a photoresist (not shown). In some embodiments, an anti-reflective coating (ARC) layer (not shown) may be formed prior to forming the photoresist, which can be formed on the ARC layer. The layer of photoresist can be imaged with an image pattern and developed to form an etch mask. The dielectric layer 134 can be etched in accordance with the etch mask to open up trenches or openings 138 at selected locations where a diffusion break will be formed. Here, the BDI 108, the nanosheet 104 (device channels) and the gate electrode 116 are removed from a region between S/D regions 114 to form a cavity 136. The cavity 136 is self-aligned using the placeholders 130 as an etch mask. The cavity 136 can extend between the S/D regions 114. The opening 138 is an entrance region to the cavity 136. The opening 138 and cavity 136 can be formed by an anisotropic etch, e.g., a reactive ion etch (RIE) or ion beam etch (IBE). The anisotropic etch, such as a plasma dry etch, is accurately controlled. The anisotropic etch is selective to not etch materials such as S/D regions 114 and buffer 118. However, the BDI 108 is thin and easily removed relative to the thicker placeholders 130, which experience some erosion. The etch process is self-aligned once the dielectric layer 134 is opened up to expose the placeholders 130. Opening 138 includes a funnel-like shape to widen the opening 138 to permit the cavity 136 to be more easily filled.

An anisotropic etch, e.g., RIE or IBE is performed to extend the cavity 136 by removing the gate electrode 116 from between the sidewall spacers 110 in the cavity 136. The anisotropic etch is selective to not etch materials such as the sidewall spacers 110, the interlevel dielectric layer 120, S/D regions 114 and buffer 118. The cavity 136 along with the opening 138 provide a location where a diffusion break will be formed in later steps.

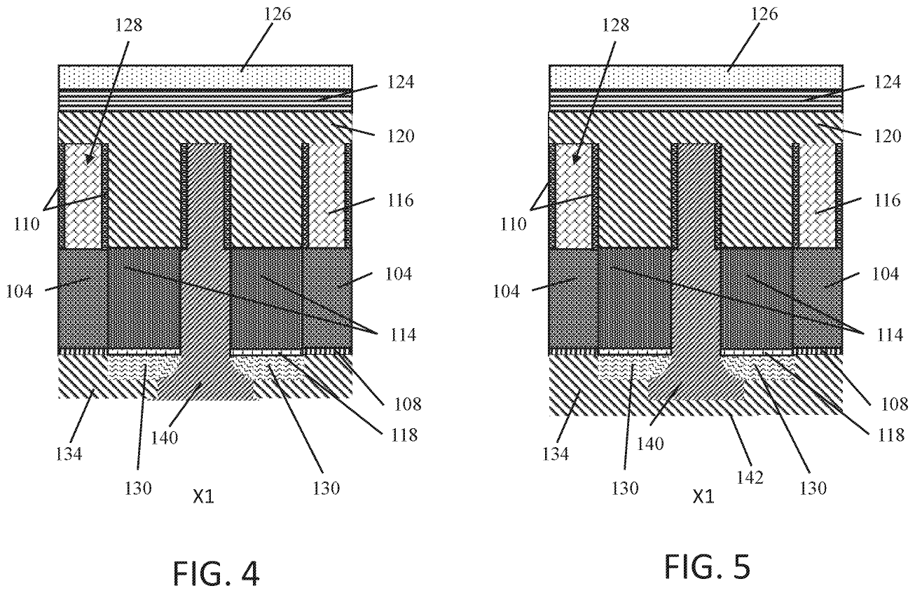

Referring to FIG. 4, a dielectric fill process is performed to fill in the cavity 136 and the opening 138. The dielectric fill can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 120 can be deposited using CVD, plasma enhanced CVD (PECVD), atomic layer deposition (ALD) although other deposition methods can be employed.

By employing a backside of the wafer 100, the opening 138 and cavity 136 do not have to be as deep, and the aspect ratio of the opening 138 and cavity 136 permit easier access and therefore an easier fill with dielectric fill. Since the aspect ratio is more favorable, the opening 138 and the cavity 136 are much more likely to be completely filled without pinch off or voids in the dielectric fill. Furthermore, opening 138 includes a funnel-shaped or conical-shaped opening to ensure a better and more consistent dielectric fill. The dielectric fill can be planarized, e.g., by CMP to remove access material of the dielectric fill to form a diffusion break 140.

Referring to FIG. 5, a dielectric layer 142 can optionally be deposited to enhance dielectric layer 134. By building up dielectric layer 134, larger contacts can be formed. For example, since contacts include a tapered shape, a greater height will add more conductive material to the contacts. This will permit a larger landing position for future-formed contacts or later-formed metal structures. The dielectric layer 142 can include a same material as dielectric layer 134, although a different dielectric material can be employed. The dielectric layer 142 can be planarized, e.g., by CMP to remove access material from a free surface of the device.

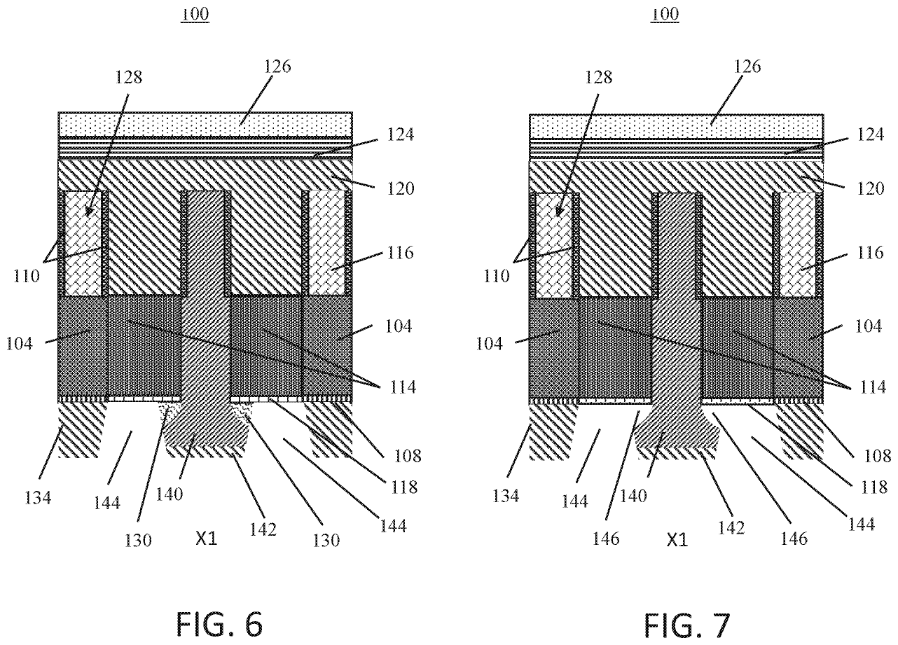

Referring to FIG. 6, a mask material (not shown) is deposited or spun onto a surface of the wafer 100. In one embodiment, the mask material includes a hard mask material that can be patterned using photolithography, e.g., using a photoresist (not shown). In some embodiments, an anti-reflective coating (ARC) layer (not shown) may be formed prior to forming the photoresist, which can be formed on the ARC layer. The layer of photoresist can be imaged with an image pattern and developed to form an etch mask. The dielectric layer 134, dielectric layer 142 (if present) and portions of placeholders 130 can be etched in accordance with the etch mask to open up contact holes 144 at selected locations where backside S/D region contacts will be formed. The etch stops on the buffer 118, which protects the S/D regions 114. The contact holes 144 can be formed by an anisotropic etch, e.g., RIE or IBE. The anisotropic etch, such as a plasma dry etch, can be employed to accurately form the contact holes 144.

Referring to FIG. 7, a portion of the placeholder 130 shadowed by the diffusion break 140 is removed to open up regions 146. An etch process e.g., a wet etch, selectively removes the material of the placeholders 130 while leaving the buffer 118 and dielectric materials for the dielectric layers 134, 142 and diffusion break 140 virtually intact. The regions 146 provide additional space for contacts to be formed. The additional space of regions 146 is directly adjacent to the S/D regions 114 where a good interface with contacts to be formed can ensure a low contact resistance. Lower contact resistance improves device performance.

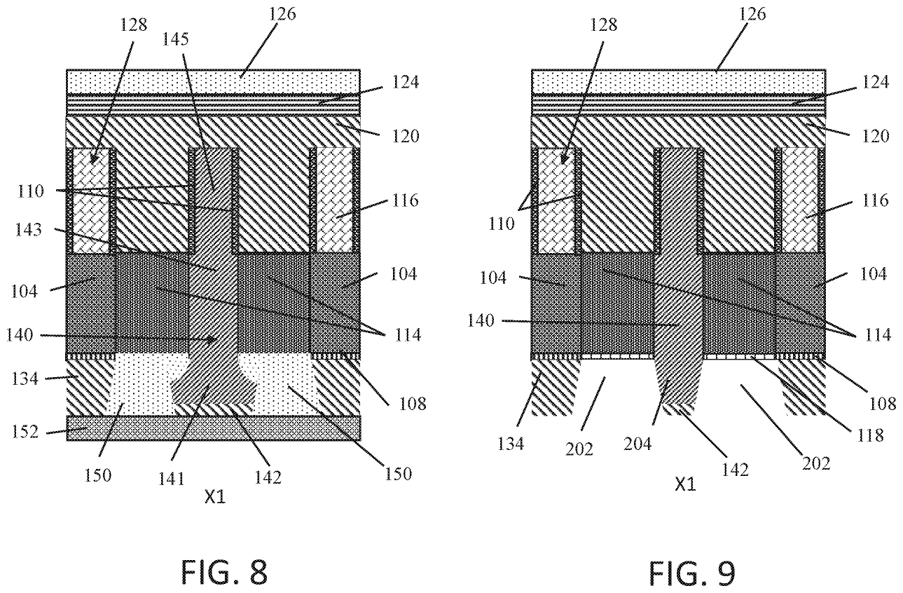

Referring to FIG. 8, buffers 118 are removed by a selective etch process, which exposes the S/D regions 114. A pre-clean of the exposed surfaces of the S/D regions 114 can be performed. In useful embodiments, a silicide liner, such as Ti, Ni, NiPt can be deposited first, then a diffusion barrier can be formed in the contact holes 144 and regions 146 prior to a conductive fill. The diffusion barrier can include, e.g., TiN, TaN, or similar materials. A conductive fill is performed to fill the contact holes 144 and regions 146. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill can be planarized, e.g., by CMP, to remove excess material of the conductive fill and to form backside contacts 150 that make connections with S/D regions 114 from a bottom side of the device.

The diffusion break 140 includes a lower portion or contact region portion 141 that is relatively wider than a S/D region portion 143. Said differently, a lateral dimension of the contact region portion 141 of the diffusion break 140 is greater than a lateral dimension of the S/D region portion 143 of the diffusion break 140. In an embodiment, the contact region portion 141 is wider than the S/D region portion 143 of the diffusion break 140 between the two adjacent source/drain regions 114 to provide additional dielectric material between the S/D region contacts 150. The contact region portion 141 of the diffusion break 140 can narrow toward the two adjacent source/drain regions 114 to maximize contact surface area between the S/D region contacts 150 and the source/drain regions 114.

An upper portion or gate region portion 145 of the diffusion break 140 is disposed between sidewall spacers 110. The gate region portion 145 is narrower than the diffusion break 140 between the two adjacent source/drain regions 114. Said differently, a lateral dimension of the gate region portion 145 of the diffusion break 140 is less than a lateral dimension of the S/D region portion 143 of the diffusion break 140.

Processing continues with the formation of a backside power distribution network (BSPDN) 152, which can include metal structures and dielectric layers to complete the bottom side of the device and provide electrical access to the devices formed. The BSPDN 152 connects to the backside contacts 150.

Other configurations and combinations of configurations are contemplated for the diffusion break 140. In one example, the diffusion break 140 can include a narrower profile and the backside contacts can be made larger.

Referring to FIG. 9, in another embodiment a wafer 200 is processed, beginning with the structure of FIG. 5, placeholders 130 are removed and larger contact holes 202 are patterned. The larger contact holes are created by removing remnants of placeholders 130 as well as removing or trimming portions of a diffusion break 240 to form a wedge-shape 204 on a backside of the diffusion break 240. To form the larger contact holes 202, a mask material (not shown) is deposited or spun onto a surface of the wafer 200. In one embodiment, the mask material includes a hard mask material that can be patterned using photolithography, e.g., using a photoresist (not shown). In some embodiments, an anti-reflective coating (ARC) layer (not shown) may be formed prior to forming the photoresist, which can be formed on the ARC layer. The layer of photoresist can be imaged with an image pattern and developed to form an etch mask. The dielectric layer 134, dielectric layer 142 (if present) and placeholders 130 can be etched in accordance with the etch mask to open up contact holes 202 at selected locations where backside S/D region contacts will be formed. The etch stops on the buffer 118, which protects the S/D regions 114. The buffer 118 can be removed as needed in later steps. The contact holes 202 can be formed by an anisotropic etch, e.g., RIE or IBE. The anisotropic etch, such as a plasma dry etch, can be employed to accurately form the contact holes 202.

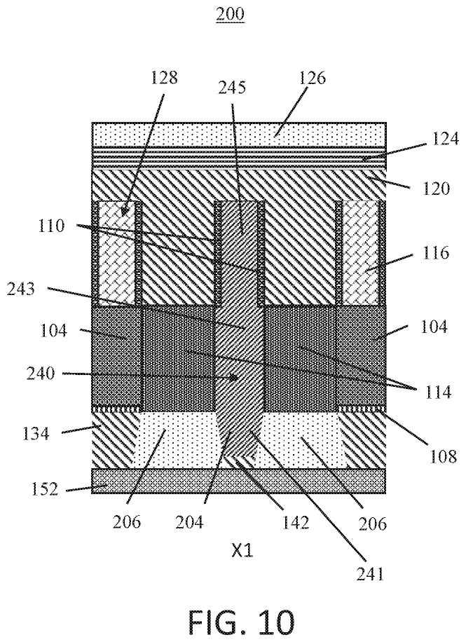

Referring to FIG. 10, buffers 118 are removed by a selective etch process, which exposes the S/D regions 114. A pre-clean of the exposed surfaces of the S/D regions 114 can be performed. In useful embodiments, a silicide liner, such as Ti, Ni, NiPt can be deposited first, then a diffusion barrier can be formed in the contact holes 202 prior to a conductive fill. The diffusion barrier can include, e.g., TiN, TaN, or similar materials. A conductive fill is performed to fill the contact holes 202. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill can be planarized, e.g., by CMP to remove excess material of the conductive fill to form backside contacts 206 that make connections with S/D regions 114 from a bottom side of the device.

Processing continues with the formation of a backside power distribution network (BSPDN) 152, which can include metal structures and dielectric layers to complete the backside of the device and provide electrical access to the devices formed. The BSPDN 152 connects to the backside contacts 206.

The diffusion break 240 includes a lower or contact region portion 241 that includes a narrower portion than a S/D region portion 243. Said differently, a lateral dimension of the contact region portion 241 of the diffusion break 240 is less than or equal to a lateral dimension of the S/D region portion 243 of the diffusion break 240. In an embodiment, the contact region portion 241 is narrower than the S/D region portion 243 of the diffusion break 240 between the two adjacent source/drain regions 114 to provide additional material for the S/D region contacts 206. The contact region portion 241 permits larger contacts and maximizes contact surface area between the S/D region contacts 206 and the source/drain regions 114. The lower portion or contact region portion 241 includes a tapered shape to permit larger sized contacts.

An upper portion or gate region portion 245 of the diffusion break 240 is disposed between sidewall spacers 110. The gate region portion 245 is narrower than the diffusion break 240 between the two adjacent source/drain regions 114. Said differently, a lateral dimension of the gate region portion 245 of the diffusion break 240 is less than a lateral dimension of the S/D region portion 243 of the diffusion break 240.

A single diffusion break (SDB) 140, 240 or, simply, diffusion break can be formed locally to backside S/D regions 114. The diffusion break 140, 240 electrically isolates two adjacent S/D regions 114 by preventing electrical conduction between the adjacent source/drain regions. The diffusion break 140, 240 can be formed with reduced risk of pinched off dielectric that can prevent dielectric fill of the cavity formed between S/D regions 114. A lower aspect ratio is achieved for the cavity and a deep fill trench is avoided. The present embodiments leverage the less populated backside of the device to create more favorable aspect ratios and therefore provide larger fill openings. This results in increased reliability in the dielectric filling of diffusion breaks in accordance with embodiments of the present invention. A more reliable fill results in a more reliable diffusion break.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom,” “backside,” “frontside” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
source/drain regions laterally disposed relative to one another in a row; and
a diffusion break disposed between two adjacent source/drain regions and extending toward a backside of the semiconductor device between two source/drain region contacts, the diffusion break including a different lateral dimension between the two adjacent source/drain regions than between the two source/drain region contacts.

2. The semiconductor device as recited in claim 1, wherein the diffusion break includes a portion that extends beyond the source/drain regions opposite the backside of the semiconductor device.

3. The semiconductor device as recited in claim 2, wherein the portion of the diffusion break includes sidewall spacers.

4. The semiconductor device as recited in claim 1, wherein the diffusion break includes a wider portion between the two source/drain region contacts than between the two adjacent source/drain regions.

5. The semiconductor device as recited in claim 4, wherein the wider portion of the diffusion break narrows toward the two adjacent source/drain regions.

6. The semiconductor device as recited in claim 1, wherein the diffusion break extends between a replacement metal gate layer to a backside power distribution network.

7. The semiconductor device as recited in claim 6, further comprising a backside interlevel dielectric layer disposed between the backside power distribution network and the diffusion break.

8. The semiconductor device as recited in claim 1, wherein the diffusion break includes a narrower portion between the two source/drain region contacts than between the two adjacent source/drain regions to permit the two source/drain region contacts to be larger.

9. The semiconductor device as recited in claim 1, wherein the diffusion break is disposed in a gate region and the diffusion break replaces a gate.

10. The semiconductor device as recited in claim 1, wherein the diffusion break is disposed in a device channel region and the diffusion break replaces a device channel.

11. A semiconductor device, comprising:
a frontside and a backside opposite the frontside;
source/drain regions laterally disposed relative to one another;
backside source/drain region contacts connected to two adjacent source/drain regions from the backside; and
a diffusion break disposed between the two adjacent source/drain regions and having an upper portion and a lower portion, the upper portion being disposed in a gate region and the lower portion separating the backside source/drain region contacts.

12. The semiconductor device as recited in claim 11, wherein the upper portion of the diffusion break includes sidewall spacers.

13. The semiconductor device as recited in claim 11, wherein the diffusion break includes a wider portion between the backside source/drain region contacts than between the source/drain regions.

14. The semiconductor device as recited in claim 13, wherein the wider portion of the diffusion break narrows toward the source/drain regions.

15. The semiconductor device as recited in claim 11, wherein the diffusion break extends between a replacement metal gate layer to a backside power distribution network.

16. The semiconductor device as recited in claim 15, further comprising a backside interlevel dielectric layer disposed between the backside power distribution network and the lower portion of the diffusion break.

17. The semiconductor device as recited in claim 11, wherein the diffusion break includes a narrower portion between the backside source/drain region contacts than between the source/drain regions to permit the backside source/drain region contacts to be larger.

18. The semiconductor device as recited in claim 11, wherein the diffusion break is disposed in a gate region and the diffusion break replaces a gate.

19. The semiconductor device as recited in claim 11, wherein the diffusion break is disposed in a device channel region and the diffusion break replaces a device channel.

20. A semiconductor device, comprising:
a frontside and a backside opposite the frontside;
source/drain regions laterally disposed relative to one another; and
a diffusion break disposed between two adjacent source/drain regions and having an upper portion and a lower portion,
the upper portion being disposed in a gate region, and
the lower portion separating backside source/drain region contacts, the lower portion having a wider portion between the backside source/drain region contacts than between the source/drain regions such that a contact area between respective backside source/drain region contacts and corresponding source/drain regions is increased.

21. The semiconductor device as recited in claim 20, wherein the upper portion of the diffusion break includes sidewall spacers.

22. A semiconductor device, comprising:
a frontside and a backside opposite the frontside;
source/drain regions laterally disposed relative to one another;
backside source/drain region contacts connected to two adjacent source/drain regions from the backside;
a diffusion break disposed between the two adjacent source/drain regions and having an upper portion and a lower portion, the upper portion being disposed in a gate region and the lower portion separating the backside source/drain region contacts, the diffusion break includes a wider portion between the backside source/drain region contacts than between the source/drain regions, the wider portion narrows toward the source/drain regions; and
a backside interlevel dielectric layer disposed between a backside power distribution network and the lower portion of the diffusion break.

23. The semiconductor device as recited in claim 22, wherein the upper portion of the diffusion break includes sidewall spacers.

24. The semiconductor device as recited in claim 22, wherein the diffusion break extends between a replacement metal gate layer to the backside power distribution network.

25. A semiconductor device, comprising:
a frontside and a backside opposite the frontside;
source/drain regions laterally disposed relative to one another;
backside source/drain region contacts connected to two adjacent source/drain regions from the backside;
a diffusion break disposed between the two adjacent source/drain regions and having an upper portion and a lower portion, the upper portion being disposed in a gate region and the lower portion separating the backside source/drain region contacts, the lower portion of the diffusion break including a tapered shape between the backside source/drain region contacts to permit the backside source/drain region contacts to be larger; and
a backside interlevel dielectric layer disposed between a backside power distribution network and the lower portion of the diffusion break.
